(19) United States
(12) Patent Application Publication
(10) Pub. No.: US 2026/0113856 A1
(43) Pub. Date: Apr. 23, 2026

(54) CHARGING DEVICE

(71) Applicant: LG ELECTRONICS INC., Seoul (KR)

(72) Inventors: Jiho LEE, Seoul (KR); Kangsuk LEE, Seoul (KR); Junyeop JEONG, Seoul (KR); Sunghwan OH, Seoul (KR); Myoungku LEE, Seoul (KR)

(73) Assignee: LG ELECTRONICS INC., Seoul (KR)

(21) Appl. No.: 18/975,224

(22) Filed: Dec. 10, 2024

(30) Foreign Application Priority Data
Oct. 18, 2024 (KR) 10-2024-0142699

(51) Int. Cl. H05K 5/02; B60L 53/16; B60L 53/18; B60L 53/31; G09F 9/30; H02J 7/00; H05K 7/20

(52) U.S. Cl. CPC H05K 5/0217; B60L 53/18; B60L 53/31; G09F 9/30; H02J 7/70; B60L 53/16; H05K 7/20954

(57) ABSTRACT

Disclosed herein is a charging device including a display module, and a body having a front portion allowing the display module to be disposed thereon, wherein a charger connected to a cable is disposed on the body, wherein the front portion of the body includes a coupling surface including a rim shape coupled to a rim of a rear surface of the display module, the coupling surface having a size corresponding to the rear surface of the display module, and an exposed surface defining a surface aligned with the front surface of the display module. The charging device allows the display module to be seamlessly disposed on the front portion of the body.

### CROSS-REFERENCE TO RELATED APPLICATIONS

Pursuant to 35 U.S.C. § 119(a), this application claims the benefit of earlier filing date and right of priority to Korean Patent Application No. 10-204-0142699, filed on Oct. 18, 2024, the contents of which are all hereby incorporated by reference herein in their entireties.

### BACKGROUND

### Field

The present disclosure relates to a charging device allowing a display module to be seamlessly disposed on a front portion of the charging device for charging an electric vehicle.

### Discussion of the Related Art

In general, an electric vehicle (EV) has not been put into practical use for a long time because of problems such as a great weight of a battery mounted in the vehicle and a time it takes to charge when compared to a gasoline or diesel vehicle. However, recently, because of a depletion of fossil energy and environmental pollution, interest in the electric vehicle that does not use the fossil energy but uses electric energy has increased, and research and development on the electric vehicle have been actively conducted.

As a result, popularization of the electric vehicle has been increasing recently. The electric vehicle has a battery that supplies power for operation thereof, and has a structure in which the power is stored in the battery. Therefore, to continuously operate the electric vehicle, the battery must be charged. Accordingly, an infrastructure for charging the electric vehicle is needed, and fixed standing charging facilities are being established in various locations to meet an increasing demand for the electric vehicle.

In this regard, a charging device of the electric vehicle is an element for building a stable charging infrastructure that maintains electrical stability and long-term lifespan. This is because the charging device of the electric vehicle is mainly installed outdoors, such as a parking lot of a public building or a park, a highway rest area, and an apartment complex.

In addition, in a case of the electric vehicle that requires frequent charging, it is necessary to ensure visibility of the charging device even at night for convenience of a user. Additionally, to further improve the convenience of the user, a means to easily check a charged state of the electric vehicle is also needed.

Further, as described above, since the charging facilities for electric vehicles are installed in various places, the charging facilities for electric vehicles are used not only for charging the electric vehicles, but also for external advertisements through images displayed.

Therefore, in order to meet the various needs of consumers described above, a structural means allowing for stable arrangement of the display module in the charging facility for electric vehicles and having an excellent design is required.

### SUMMARY OF THE DISCLOSURE

The present disclosure is directed to a charging device. More particularly, an object of the present disclosure is to provide a charging device in which a display module can be seamlessly disposed on a front portion of a body.

Another object of the present disclosure is to provide a charging device capable of forming a structural unity, wherein the front portion of the body includes a coupling surface having a size corresponding to a rear surface of the display module and an exposed surface defining a surface that is aligned with the front surface of the display module.

Another object of the present disclosure is to provide a charging device capable of increasing the structural rigidity of the body with a frame coupled to the interior of a case.

Additional advantages, objects, and features of the disclosure will be set forth in part in the description which follows and in part will become apparent to those having ordinary skill in the art upon examination of the following or may be learned from practice of the disclosure.

In an aspect of the present disclosure, there is provided a charging device including a display module, and a body having a front portion allowing the display module to be disposed thereon, wherein a charger connected to a cable is disposed on the body, wherein the front portion of the body includes a coupling surface including a rim shape coupled to a rim of a rear surface of the display module, the coupling surface having a size corresponding to the rear surface of the display module, and an exposed surface defining a surface aligned with the front surface of the display module.

The body may include a first case including the coupling surface, and a second case disposed under the first case, the second case including the exposed surface.

The body may include a pair of fastening members coupled to opposite sides of a top surface of the second case in an upright position, wherein the first case may include a pair of fitting grooves formed on a bottom surface thereof, the pair of fastening members to be fitted into the fitting grooves.

The pair of fastening members may include a fastening surface coupled to an inner side surface of the first case, and a support surface bent perpendicularly on the fastening surface to protrude from the inner side surface of the first case.

The body may include a first frame part coupled to inner surfaces of the first case and the second case to increase structural rigidity of the first case and the second case.

The first case and the second case may each include a plurality of slits formed therein to be fitted onto the first frame part from a front side rearward.

The first frame part may include a pair of first support frames disposed upright and spaced apart from each other to support a rear surface of the display panel.

The body may include a pair of fixing members coupled to opposite sides of a rear surface of the coupling surface, wherein the coupling surface and the pair of fixing members may each include a plurality of fastening holes, the fastening holes of the coupling surface being formed at positions corresponding to positions of the fastening holes of the pair of fixing members.

The body may include a cover part defining the coupling surface and the exposed surface, wherein the cover part may include a top cover bent to form a top portion of the coupling surface, a pair of side covers bent to form two side portions of the coupling surface, and a front cover bent to form a bottom portion of the coupling surface and the exposed surface.

The body may include a second frame part coupled to an inner surface of the cover part to increase structural rigidity of the cover part.

The second frame part may be bent to support the coupling surface and the exposed surface formed by the cover part.

The second frame part may include a pair of second support frames disposed upright and spaced apart from each other to support a rear surface of the display panel.

The second frame part may include a base frame allowing a lower portion of the cover part to be seated thereon, and a base plate having a top surface coupled to the base frame.

The charging device may further include a rear cover disposed on a rear portion of the body, wherein the rear cover may include a first cover disposed to face the coupling surface, and a second cover disposed to face the exposed surface.

The rear cover may be rotatably coupled to the rear portion of the body.

The body may include a cable connector formed on a side portion thereof, wherein the cable connector may include a wire withdrawn from and retracted into the side portion, the wire having one end connected to the cable, a weight connected to an opposite end of the wire, and a guide rail arranged to guide movement of the weight.

The charger is disposed on one of the exposed surface of the body, the rear cover, and the side portion.

The charging device may further include an accommodation box seated inside the body to accommodate an electronic component configured to supply power to the cable.

The display module may include a display panel configured to output an image, and a cover bracket arranged to cover a rear surface of the display panel, the cover bracket being coupled to the front portion of the body, wherein the cover bracket may include a sealing member coupled to a rim thereof to blocks a gap between the cover bracket and the coupling surface.

The cover bracket may include an exhaust hole allowing heat generated from the display panel to dissipate therethrough.

In a charging device according to the present disclosure, a display module may be seamlessly disposed on a front portion of a body.

Further, the front portion of the body may include a coupling surface having a size corresponding to a rear surface of the display module and an exposed surface defining a surface that is aligned with the front surface of the display module, thereby forming a structural unity.

Further, the structural rigidity of the body may be increased with a frame coupled to the interior of a case.

The effects that can be achieved with the present disclosure are not limited to those mentioned above, and other effects not mentioned will become apparent to those skilled in the art to which the present disclosure belongs from the following description.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a perspective view of a charging device according to one embodiment of the present disclosure;

FIG. 2 is a perspective view illustrating a display module disposed on a front portion of a body in the charging device according to one embodiment of the present disclosure;

FIG. 3 is a rear view of the display module in the charging device according to one embodiment of the present disclosure;

FIG. 4 is an exploded view of a first case and a second case of the body in the charging device according to one embodiment of the present disclosure;

FIG. 5 is a view illustrating the first case and second case coupled by a fastening member in the charging device according to one embodiment of the present disclosure;

FIG. 6 is a view illustrating a pair of fixing members coupled to opposite sides of a rear surface of a coupling surface in the charging device according to one embodiment of the present disclosure;

FIG. 7 is a view illustrating a first frame part coupled to inner surfaces of the first case and second case in the charging device according to one embodiment of the present disclosure;

FIG. 8 is a view illustrating the shape of the first case and the second case coupled to the first frame part in the charging device according to one embodiment of the present disclosure;

FIG. 9 is a view illustrating a cover part of the body in the charging device according to one embodiment of the present disclosure;

FIG. 10 is a view illustrating a second frame part coupled to an inner surface of the cover part in the charging device according to one embodiment of the present disclosure;

FIG. 11 is an exploded view of FIG. 10;

FIG. 12 is a view illustrating the cover part coupled to the second frame part in the charging device according to one embodiment of the present disclosure;

FIG. 13 is a view illustrating the display module coupled to a coupling surface of the cover part in the charging device according to one embodiment of the present disclosure;

FIG. 14 is a view illustrating a rear cover disposed on a rear portion of the body in the charging device according to one embodiment of the present disclosure;

FIG. 15 is a view illustrating a cable connector formed on a side portion of the body in the charging device according to one embodiment of the present disclosure; and FIG. 16 is a view illustrating a charger disposed on the body in the charging device according to one embodiment of the present disclosure.

### DETAILED DESCRIPTION OF THE DISCLOSURE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

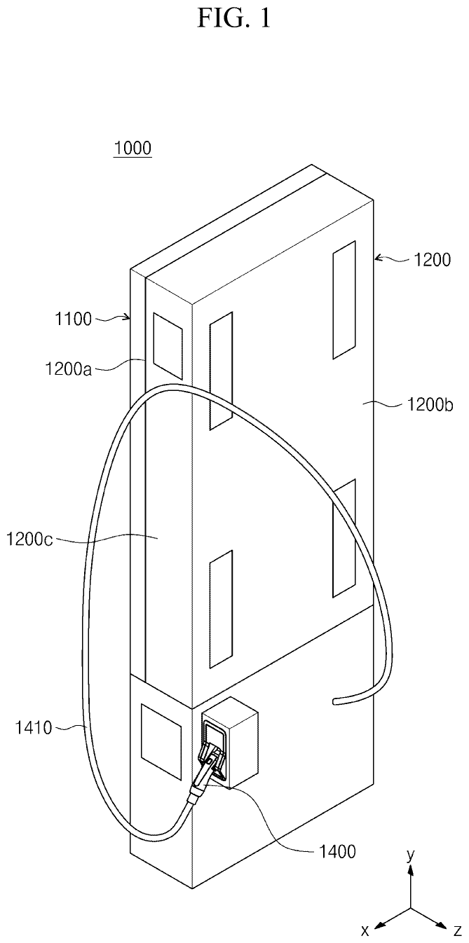

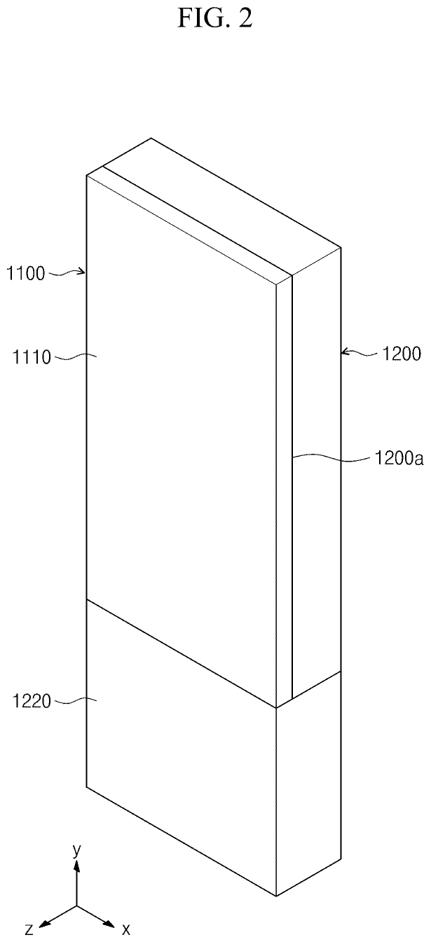

FIG. 1 is a perspective view of a charging device 1000 according to one embodiment of the present disclosure, and FIG. 2 is a perspective view illustrating a display module 1100 disposed on a front portion 1200a of a body 1200 in the charging device 1000 according to one embodiment of the present disclosure.

Hereinafter, in describing the charging device 1000 according to one embodiment of the present disclosure, the left-to-right direction will be described based on the x-axis direction, the vertical direction will be described based on the y-axis direction, and the forward and backward directions will be described based on the z-axis direction.

Referring to FIGS. 1 and 2, the charging device 1000 according to one embodiment of the present disclosure may include a display module 1100 and a body 1200. Here, the display module 1100 may include a display panel 1110 that outputs an image, and may be disposed on the front portion 1200a of the body 1200.

Further, the display panel 1110 may be inter-layered or integrated with a touch sensor to implement a touch screen. Such a touch screen may function to provide an input interface between the charging device 1000 and a user, and may also serve to provide an output interface between the charging device 1000 and the user.

The charging device 1000 according to one embodiment of the present disclosure may further include a rear cover 1300 disposed on a rear portion 1200b of the body 1200 for ease of maintenance. Here, the rear cover 1300 may be coupled to the rear portion 1200b of the body 1200 so as to be removable or to be opened and closed.

Further, the rear cover 1300 may be rotatably coupled to the rear portion 1200b of the body 1200 and may serve as a door. Thereby, the ease of maintenance described above may be secured. Further, the body 1200 may include a charger 1400 to which a cable 1410 is connected to charge the electric vehicle.

In particular, the charging device 1000 according to one embodiment of the present disclosure may seamlessly dispose the display module 1100 on the front portion 1200a of the body 1200, as shown in FIGS. 1 and 2. In other words, the charging device 1000 of the present disclosure may implement a structure without the bezel of the display module 1100.

This is because, as described above, charging facilities for electric vehicles are used not only for charging the electric vehicles, but also for external advertisements through images displayed as the charging facilities are installed in various places.

Therefore, the charging device 1000 according to one embodiment of the present disclosure is intended to provide a stable arrangement of the display module 1100 and an excellent design structure to meet various needs of consumers, as described above.

To this end, in the charging device 1000 according to one embodiment of the present disclosure, the front portion 1200a of the body 1200 may include a rim-shaped coupling surface 1210 coupled to the rim of the rear surface of the display module 1100. The coupling surface 1210 may have a size corresponding to the rear surface of the display module 1100.

Further, the front portion 1200a of the body 1200 may include an exposed surface 1220 that defines a surface that is aligned with the front surface of the display module 1100. Thus, a structural unity of the charging device 1000 may be implemented. A more detailed description will be provided later.

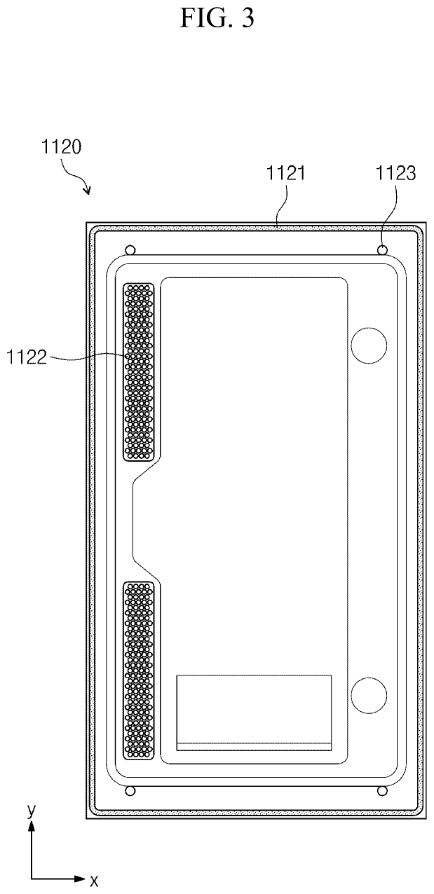

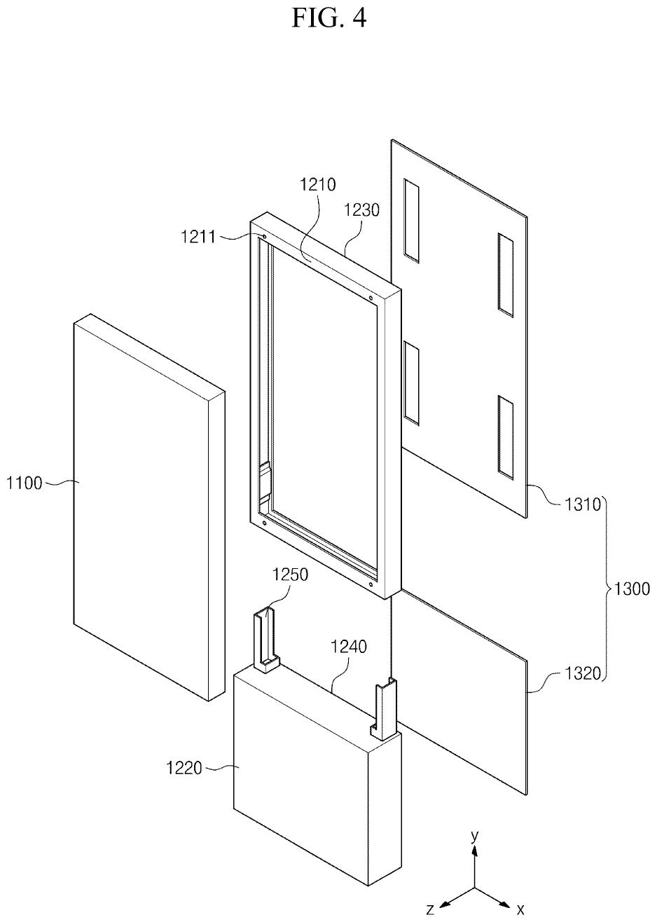

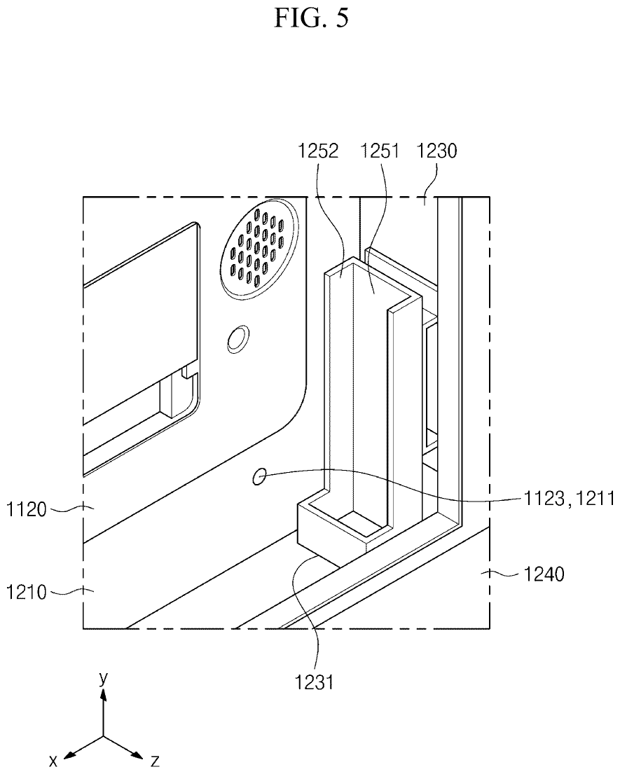

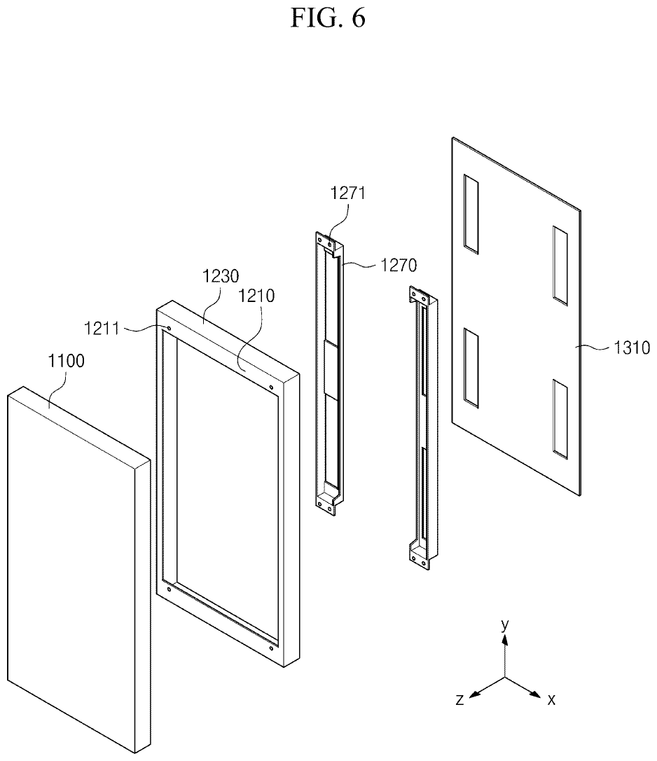

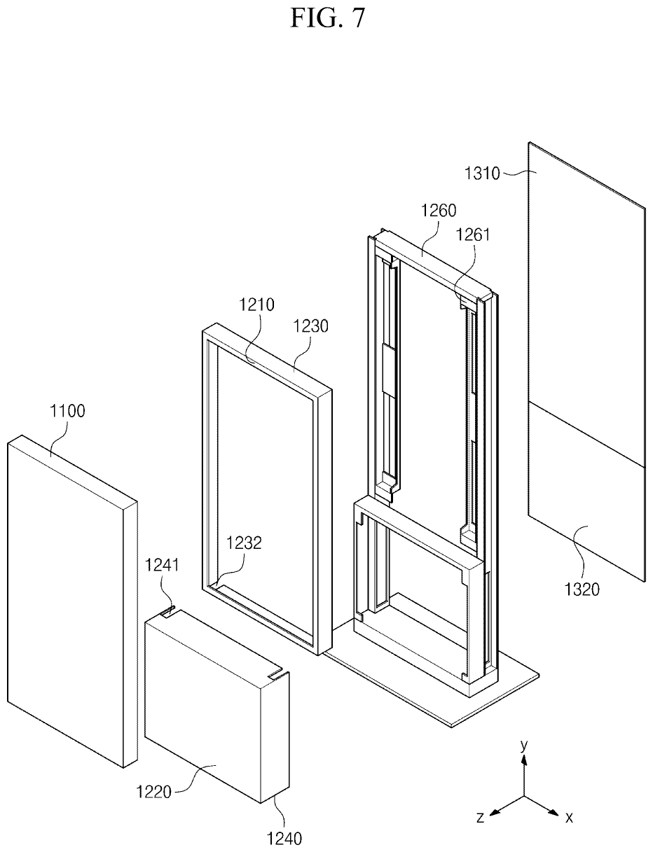

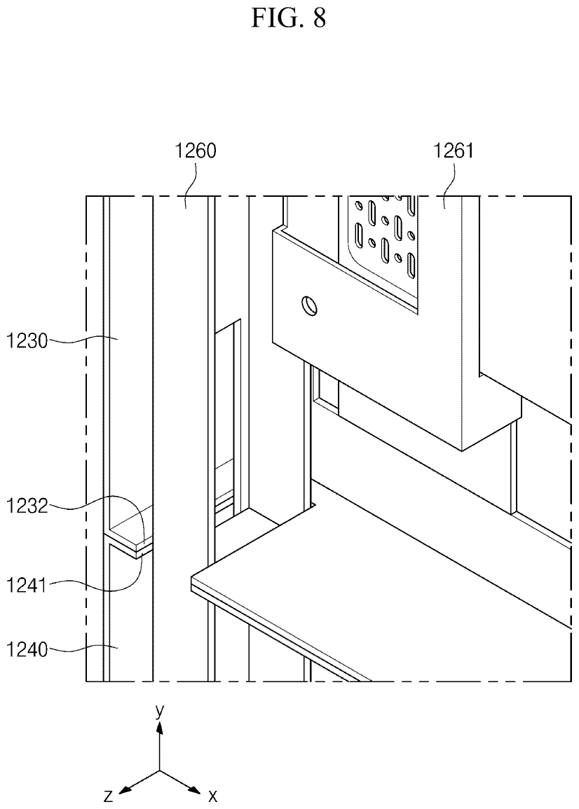

FIG. 3 is a rear view of the display module 1100 in the charging device 1000 according to one embodiment of the present disclosure. FIG. 4 is an exploded view of a first case 1230 and a second case 1240 of the body 1200 in the charging device 1000 according to one embodiment of the present disclosure. FIG. 5 is a view illustrating the first case 1230 and second case 1240 coupled by a fastening member 1250 in the charging device 1000 according to one embodiment of the present disclosure. FIG. 6 is a view illustrating a pair of fixing members 1270 coupled to opposite sides of a rear surface of the coupling surface 1210 in the charging device 1000 according to one embodiment of the present disclosure. FIG. 7 is a view illustrating a first frame part 1260 coupled to inner surfaces of the first case 1230 and second case 1240 in the charging device 1000 according to one embodiment of the present disclosure. FIG. 8 is a view illustrating the shape of the first case 1230 and the second case 1240 coupled to the first frame part 1260 in the charging device 1000 according to one embodiment of the present disclosure.

First, FIG. 3 is a rear view of the display module 1100 disposed on the front portion 1200a of the body 1200 in the charging device 1000 according to one embodiment of the present disclosure. The display module 1100 may include a cover bracket 1120 arranged to cover a rear surface of the display panel 1110. The cover bracket 1120 may be coupled to the front portion 1200a of the body 1200.

More specifically, in the charging device 1000 according to one embodiment of the present disclosure, the front portion 1200a of the body 1200 may include a rim-shaped coupling surface 1210, and the coupling surface 1210 may be coupled the rim of the rear surface of the display module 1100. To this end, multiple fastening holes 1123 may be formed in the rim of the cover bracket 1120 for coupling to the coupling surface 1210.

Further, in the charging device 1000 according to one embodiment of the present disclosure, the cover bracket 1120 may include a sealing member 1121 that is coupled to the rim thereof and seal a gap between the cover bracket 1120 and the coupling surface 1210. Here, the sealing member 1121 may include a rubber member made of, for example, silicone.

This is because, as described above, the charging device 1000, which is mainly installed outdoors, is exposed to the external environment and, in particular, a means for waterproofing the charging device 1000 is essential for electrical stability and long-term service life of the charging device 1000.

Therefore, the charging device 1000 according to one embodiment of the present disclosure may secure electrical stability and the like through a waterproof structure by sealing a possible gap between the display module 1100 and the body 1200 coupled thereto with the sealing member 1121.

Further, in the charging device 1000 according to one embodiment of the present disclosure, the cover bracket 1120 of the display module 1100 may include exhaust holes 1122, which is provided to dissipate heat generated from the display panel 1110. In addition, the display module 1100 may be provided therein with a component, such as a blower, to dissipate heat through the exhaust holes 1122 formed in the cover bracket 1120.

Referring to FIG. 4, in the charging device 1000 according to one embodiment of the present disclosure, the body 1200 may include the first case 1230 and the second case 1240. Here, the first case 1230 may include the rim-shaped coupling surface 1210 described above. The second case 1240 may include the exposed surface 1220 that is disposed under the first case 1230 and defines a surface aligned with the front surface of the display module 1100.

Further, as shown in FIG. 4, in the charging device 1000 according to one embodiment of the present disclosure, the rear cover 1300 may include a first cover 1310 disposed to face the coupling surface 1210 and a second cover 1320 facing the exposed surface 1220. Specifically, the first cover 1310 may be coupled to the first case 1230 so as to be removable or to be opened and closed, and the second cover 1320 may be coupled to the second case 1240 so as to be removable or to be opened and closed.

Further, the first cover 1310 may be rotatably coupled to the first case 1230 and the second cover 1320 may be rotatably coupled to the second case 1240 to serve as doors as described above. Thereby, the ease of maintenance described above may be secured.

Further, referring to FIGS. 4 and 5, in the charging device 1000 according to one embodiment of the present disclosure, the body 1200 may include a pair of fastening members 1250 coupled to opposite sides of the top surface of the second case 1240 in an upright position. The first case 1230 may include a pair of fitting grooves 1231 formed on the bottom surface to allow the pair of fastening members 1250 to be fitted thereinto.

In other words, the first case 1230 and the second case 1240 may be coupled to each other by the pair of fasteners 1250. Thereby, the first case 1230 to which the rear surface of the display module 1100 is coupled may be stably supported.

Additionally, the pair of fastening members 1250 may include a fastening surface 1251 coupled to an inner side surface of the first case 1230. The inner surface of the first case 1230 and the fastening surface 1251 may be coupled using a coupling method, such as screw-coupling. Further, the pair of fastening members 1250 may include a support surface 1252 that is bent perpendicularly on the fastening surface 1251 to protrude from an inner side surface of the first case 1230. This configuration may ensure that the first case 1230 is stably supported and may increase the structural rigidity of the body 1200.

Further, referring to FIG. 6, in the charging device 1000 according to one embodiment of the present disclosure, the body 1200 may include a pair of fixing members 1270 coupled to opposite sides of the coupling surface 1210. Here, the coupling surface 1210 and the pair of fixing members 1270 may include multiple coupling holes 1211 and 1271 formed at positions corresponding to each other. Specifically, first coupling holes 1211 formed in the coupling surface 1210 and second coupling holes 1271 formed in the pair of fixing members 1270 may be formed at positions corresponding to each other.

Further, the rear surface of the display panel 1110 may be coupled to the coupling surface 1210 through the multiple coupling holes 1211 and 1271 and the fastening holes 1123 formed in the cover bracket 1120 described above with reference to FIG. 3.

Accordingly, as the coupling surface 1210 to which the rim of the rear surface of the display module 1100 is coupled is formed to have a size corresponding to the rear surface of the display module 1100, the charging device 1000 according to one embodiment of the present disclosure may achieve a seamless effect, while still allowing the display module 1100 to be securely coupled to the coupling surface 1210.

Referring to FIG. 7, in the charging device 1000 according to one embodiment of the present disclosure, the body 1200 may include a first frame part 1260 that is coupled to the inner surfaces of the first case 1230 and the second case 1240 to increase the structural rigidity of the first case 1230 and the second case 1240.

Referring to FIG. 8, in the charging device 1000 according to one embodiment of the present disclosure, the first case 1230 and the second case 1240 may include multiple slits 1232, 1241 formed to be fitted onto the first frame part 1260 from a front side rearward.

Specifically, first slits 1232 may be formed in the first case 1230, and second slits 1241 may be formed in the second case 1240 at positions corresponding to the first slits 1232. Thereby, the first case 1230 and the second case 1240 having the multiple slits 1232, 1241 formed therein may be fitted and coupled to the first frame part 1260 as shown in FIG. 8.

Additionally, in the charging device 1000 according to one embodiment of the present disclosure, the first frame part 1260 may include a pair of first support frames 1261 that are disposed upright and spaced apart from each other to support the rear surface of the display panel 1110, as shown in FIG. 7. Here, the first support frames 1261 may contact the rear surface of the display module 1100 coupled to the coupling surface 1210. Further, the first support frames 1261 may be coupled to the cover bracket 1120 through the fastening holes 1123 in the cover bracket 1120 described above with reference to FIG. 3. Thereby, the display module 1100 may be coupled to the coupling surface 1210 and securely fixed.

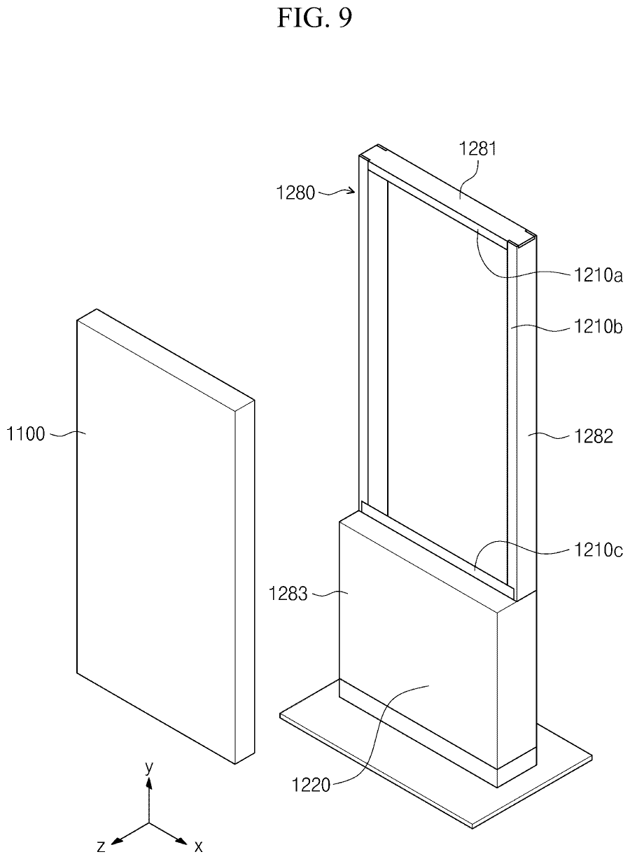

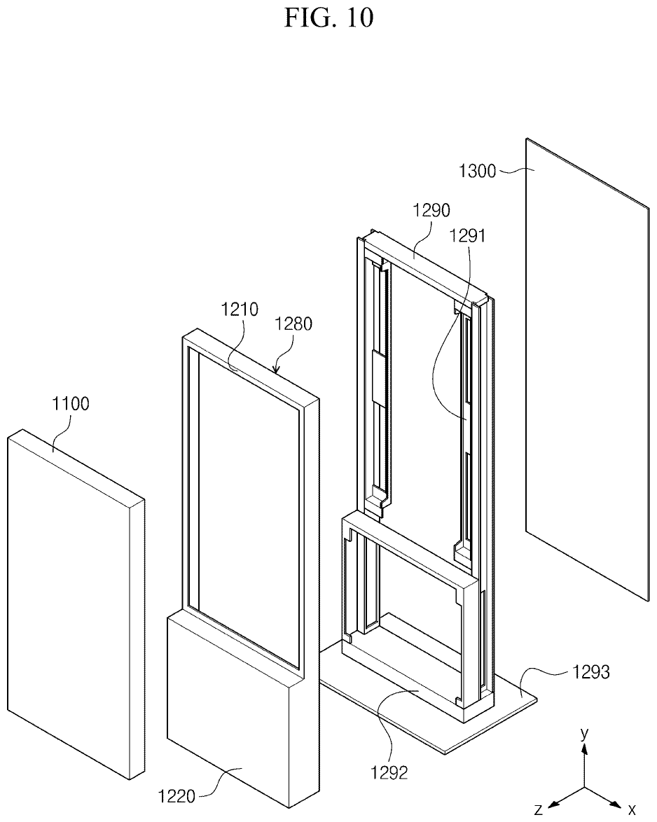

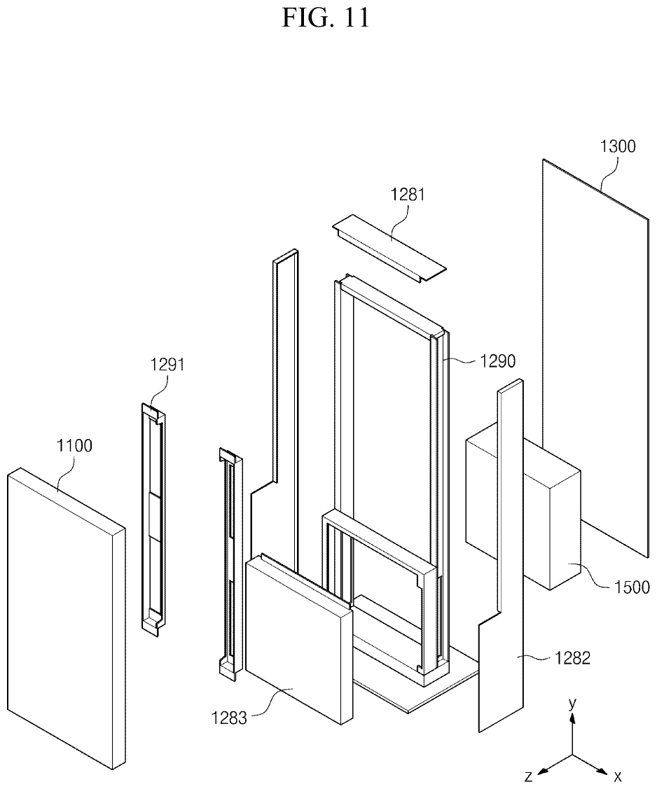

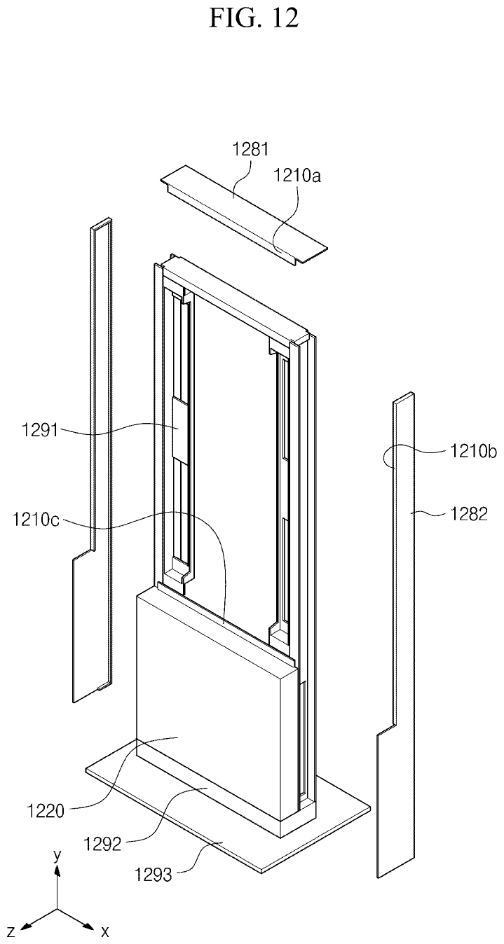

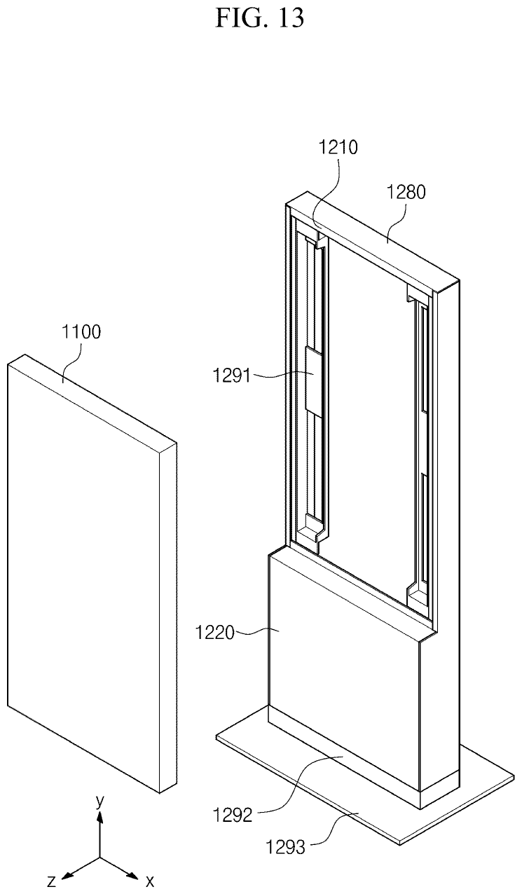

FIG. 9 is a view illustrating a cover part 1280 of the body 1200 in the charging device 1000 according to one embodiment of the present disclosure. FIG. 10 is a view illustrating a second frame part 1290 coupled to an inner surface of the cover part 1280 in the charging device 1000 according to one embodiment of the present disclosure. FIG. 11 is an exploded view of FIG. 10. FIG. 12 is a view illustrating the cover part 1280 coupled to the second frame part 1290 in the charging device 1000 according to one embodiment of the present disclosure. FIG. 13 is a view illustrating the display module 1100 coupled to the coupling surface 1210 of the cover part 1280 in the charging device 1000 according to one embodiment of the present disclosure.

As shown in FIG. 9, in the charging device 1000 according to one embodiment of the present disclosure, the body 1200 may include a cover part 1280 defining the coupling surface 1210 and the exposed surface 1220. Here, the cover part 1280 may include a top cover 1281 bent to form a top portion 1210a of the coupling surface 1210, and a pair of side covers 1282 bent to form two side portions 1210b of the coupling surface 1210. Further, the cover part 1280 may include a front cover 1283 bent to form a bottom portion 1210c of the coupling surface 1210 and the exposed surface 1220.

Accordingly, the body 1200 of the charging device 1000 according to one embodiment of the present disclosure may realize a seamless effect and a simplified structure by forming the coupling surface 1210 and the exposed surface 1220 with the cover part 1280, which is formed by coupling the top cover 1281, the pair of side covers 1282, and the front cover 1283 together, and coupling the display module 1100 thereto, as shown in FIG. 9.

Further, referring to FIGS. 10 to 13, in the charging device 1000 according to one embodiment of the present disclosure, the body 1200 may include a second frame part 1290 that is coupled to the inner surface of the cover part 1280 to increase the structural rigidity of the cover part 1280. With the second frame part 1290, structural rigidity may be secured in the structure described above with reference to FIG. 9.

To this end, the second frame part 1290 may be bent to support the coupling surface 1210 and the exposed surface 1220 formed by the cover part 1280. That is, the second frame part 1290 may be bent such that the front surface formed by the bending contacts the rear side of the coupling surface 1210 and the exposed surface 1220 to be coupled.

Also referring to FIG. 11, in the charging device 1000 according to one embodiment of the present disclosure, the second frame part 1290 may include a pair of second support frames 1291 that are disposed upright and spaced apart from each other to support the rear surface of the display panel 1110. Here, the second support frames 1291 may contact the rear surface of the display module 1100 coupled to the coupling surface 1210. Further, the second support frames 1291 may be coupled to the cover bracket 1120 through the fastening holes 1123 in the cover bracket 1120 described above with reference to FIG. 3. Thereby, the display module 1100 may be coupled to the coupling surface 1210 and securely fixed.

Additionally, in the charging device 1000 according to one embodiment of the present disclosure, the second frame part 1290 may include a base frame 1292 allowing a lower portion of the cover part 1280 to be seated thereon and a base plate 1293 having a top surface coupled to the base frame 1292.

The base frame 1292 may be formed in a size and shape corresponding to the lower portion of the cover part 1280, thereby implementing a structural unity of the charging device 1000.

Further, the base frame 1292 may have a predetermined thickness in the vertical direction (y-axis direction). Thus, even when the charging device 1000 according to one embodiment of the present disclosure is buried in an installation site, contact between the lower portion of the cover part 1280 and the ground may be avoided due to the base frame 1292 and the base plate 1293. Thereby, the durability of the cover part 1280 may be improved.

Further, referring to FIGS. 1 and 11 together, the charging device 1000 according to one embodiment of the present disclosure may include an accommodation box 1500 seated inside the body 1200 to accommodate an electronic component configured to supply power to the cable 1410. Here, the accommodation box 1500 may include a metallic material, and may contact the inner surface of the body 1200 and thus serve to increase the structural rigidity of the body 1200.

Further, for the charging device 1000 according to one embodiment of the present disclosure, the area of the display may be expanded. In other words, as described above with reference to FIGS. 1 to 13, an additional display module 1100 may be attached to the exposed surface 1220.

In this case, in order to realize the seamless effect, the first case 1230 and the second case 1240 described above with reference to FIG. 4 may be configured to have the same thickness in the front-to-back direction (z-axis direction), for example.

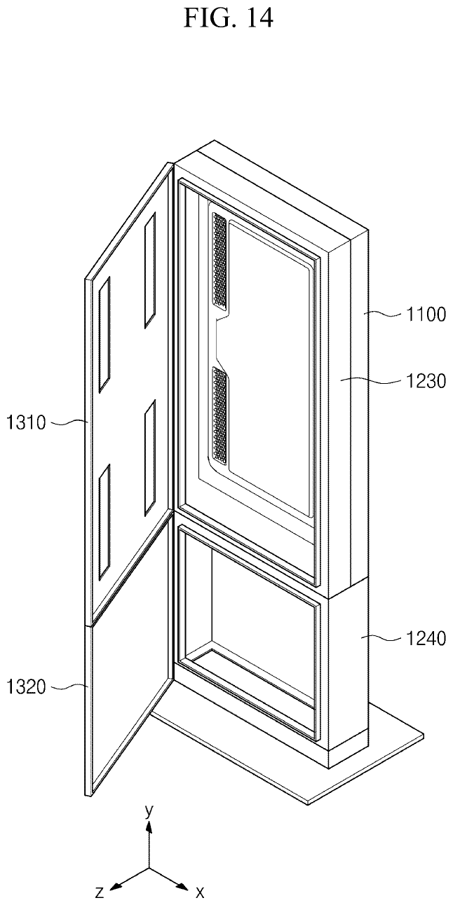

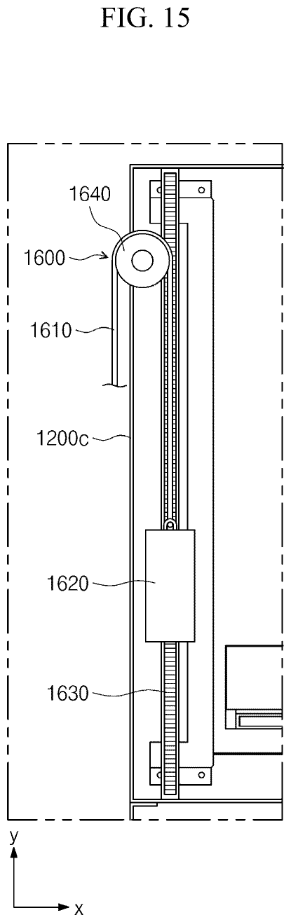

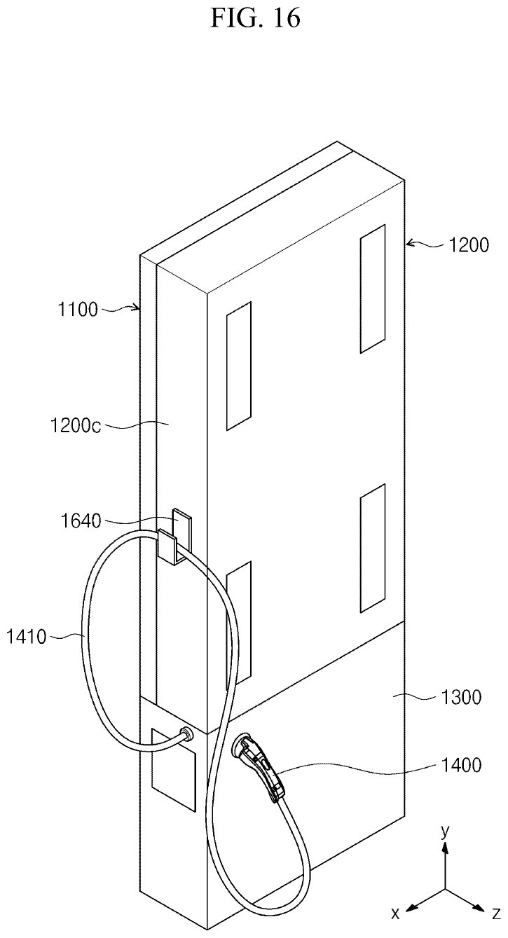

FIG. 14 is a view illustrating the rear cover 1300 disposed on the rear portion 1200b of the body 1200 in the charging device 1000 according to one embodiment of the present disclosure. FIG. 15 is a view illustrating a cable connector 1600 formed on a side portion 1200c of the body 1200 in the charging device 1000 according to one embodiment of the present disclosure. FIG. 16 is a view illustrating a charger 1400 disposed on the body 1200 in the charging device 1000 according to one embodiment of the present disclosure.

As described above, the charging device 1000 according to one embodiment of the present disclosure may include a rear cover 1300 arranged on the rear portion 1200b of the body 1200 to be openable. Further, as described above with reference to FIG. 4, the rear cover 1300 may include the first cover 1310 facing the coupling surface 1210 and the second cover 1320 facing the exposed surface 1220.

Further, referring to FIG. 14, in the charging device 1000 according to one embodiment of the present disclosure, the rear cover 1300 may be rotatably coupled to the rear portion 1200b of the body 1200. For example, one side of the rear cover 1300 and one side of the body 1200 may be hingedly coupled such that the rear cover 1300 is rotatable. That is, the rear cover 1300 may serve as a door on the body 1200. This may facilitate opening and closing of the rear cover 1300, and thus facilitate maintenance of the charging device 1000 of the present disclosure, as described above.

Referring to FIGS. 1 and 15 together, in the charging device 1000 according to one embodiment of the present disclosure, the body 1200 may include a cable connector 1600 formed on the side portion 1200c. As described above, for electric vehicles that need to be charged from time to time, a certain length of the cable 1410 to which the charger 1400 is connected should be secured for user convenience. Accordingly, a means for stable mounting of the cable 1410 is needed.

Here, one end of the cable 1410 is connected to the accommodation box 1500, which supplies power to the cable 1410 shown in FIG. 11, and the opposite end of the cable 1410 is connected to the charger 1400, which is coupled to an electric vehicle when the electric vehicle is to be charged. In order to minimize damage caused to the cable 1410 rubbing against the floor when the certain length is secured, a device is needed that allows the middle portion of the cable 1410 to be mounted to the body 1200.

Accordingly, the charging device 1000 according to one embodiment of the present disclosure may include the cable connector 1600 for stable mounting of the cable 1410. More specifically, the cable connector 1600 may include a wire 1610 withdrawn from and retracted into the side portion 1200c of the body 1200 and has one end connected to the cable 1410. Further, the cable connector 1600 may include a weight 1620 connected to the opposite end of the wire 1610 and a guide rail 1630 arranged to guide movement of the weight 1620. Additionally, the cable connector 1600 may include a roller 1640 for extension and retraction of the wire 1610.

The cable connector 1600 may allow the cable 1410, which has a certain length secured, to be stably mounted to the body 1200 with minimal damage, as described above.

Further, the charging device 1000 according to one embodiment of the present disclosure may include a cable hanger 1650 provided on the side portion 1200c of the body 1200 to simplify the structure, as shown in FIG. 16. Thus, the user may be allowed to easily mount the cable 1410.

Further, referring to FIGS. 1 and 16 together, in the charging device 1000 according to one embodiment of the present disclosure, the charger 1400 may be disposed on one of the exposed surface 1220 of the body 1200, the rear cover 1300, and the side portion 1200c.

Further, for the charging device 1000 according to one embodiment of the present disclosure, the direction in which the charger 1400 is inserted into the body 1200 may be varied to improve user convenience.

That is, the charging device 1000 according to one embodiment of the present disclosure may allow the charger 1400 to be inserted into the body 1200 in a direction perpendicular to the exposed surface 1220, the rear cover 1300, and the side portion 1200c, as shown in FIG. 16. Alternatively, as shown in FIG. 1, the charger 1400 may be inserted into the body 1200 in a direction parallel to the exposed surface 1220, the rear cover 1300, and the side portions 1200c.

In brief, the charging device according to the present disclosure may seamlessly dispose a display module on a front portion of the body. Further, the front portion of the body may form a structural unity by including a coupling surface formed in a size corresponding to the rear surface of the display module and an exposed surface defining a surface aligned with the front surface of the display module. Further, the structural rigidity of the body may be increased by using a frame coupled to the interior of the case.

The above detailed description is to be construed in all aspects as illustrative and not restrictive. The scope of the present disclosure should be determined by reasonable interpretation of the appended claims and all changes coming within the equivalency range of the present disclosure are intended to be embraced in the scope of the present disclosure.

What is claimed is:

1. A charging device comprising:
a display; and
a body having a front portion sized to receive the display;
a cable coupled to the body; and
a charger coupled to the cable,
wherein the front portion of the body comprises:
a coupling surface comprising a rim shape coupled to a rim of a rear surface of the display, wherein the coupling surface is sized to generally correspond to the rear surface of the display; and
an exposed surface defining a surface aligned with a front surface of the display.

2. The charging device of claim 1, wherein the body further comprises:
a first case comprising the coupling surface; and
a second case disposed under the first case and comprising the exposed surface.

3. The charging device of claim 2, wherein the body further comprises:
a pair of fastening members respectively coupled to opposite sides of a top surface of the second case and respectively extending from the top surface of the second case,
wherein the first case comprises a pair of fitting grooves formed on a bottom surface of the first case, and wherein each of the pair of fastening members are sized to receive a respective one of the pair of the fitting grooves.

4. The charging device of claim 3, wherein each of the pair of fastening members comprises:
a fastening surface coupled to an inner side surface of the first case; and
a support surface extending perpendicularly from the fastening surface and protruding away from the inner side surface of the first case.

5. The charging device of claim 2, wherein the body further comprises a first frame part coupled to respective inner surfaces of the first case and the second case to increase structural rigidity of the first case and the second case.

6. The charging device of claim 5, wherein the first case and the second case each comprise a plurality of slits formed therein and which are sized to couple to the first frame part from a front side of the first frame part.

7. The charging device of claim 5, wherein the first frame part comprises a pair of first support frames spaced apart from each other and which are located to support the rear surface of the display.

8. The charging device of claim 2, wherein the body further comprises a pair of fixing members coupled to opposite sides of a rear surface of the coupling surface,
wherein the coupling surface and the pair of fixing members are each shaped to define a plurality of fastening holes, wherein the fastening holes of the coupling surface are formed at positions that generally correspond to positions of the fastening holes of the pair of fixing members.

9. The charging device of claim 1, wherein the body further comprises a cover part defining the coupling surface and the exposed surface,
wherein the cover part comprises:
a top cover bent to form a top portion of the coupling surface;
a pair of side covers bent to form two side portions of the coupling surface; and
a front cover bent to form a bottom portion of the coupling surface and the exposed surface.

10. The charging device of claim 9, wherein the body further comprises a second frame part coupled to an inner surface of the cover part to increase structural rigidity of the cover part.

11. The charging device of claim 10, wherein the second frame part is bent to support the coupling surface and the exposed surface.

12. The charging device of claim 10, wherein the second frame part comprises a pair of second support frames spaced apart from each other to support the rear surface of the display.

13. The charging device of claim 10, wherein the second frame part comprises:
a base frame sized to allow a lower portion of the cover part to be seated thereon; and
a base plate having a top surface coupled to the base frame.

14. The charging device of claim 1, further comprising:
a rear cover coupled to a rear portion of the body,
wherein the rear cover comprises:
a first cover positioned to face the coupling surface; and
a second cover positioned to face the exposed surface.

15. The charging device of claim 14, wherein the rear cover is rotatably coupled to the rear portion of the body.

16. The charging device of claim 14, further comprising:
a cable connector located at a side portion of the body,
wherein the cable connector comprises:
a wire configured to be withdrawn from, and retracted into, the side portion of the body, wherein one end of the wire is coupled to the cable;
a weight connected to a second end of the wire; and
a guide rail arranged to guide movement of the weight.

17. The charging device of claim 16, wherein the charger is located on one of the exposed surface of the body, the rear cover, or the side portion.

18. The charging device of claim 1, further comprising:
a box located inside the body to accommodate an electronic component configured to supply power to the cable.

19. The charging device of claim 1, wherein the display comprises:
a display panel configured to output an image; and
a cover bracket arranged to cover a rear surface of the display panel, wherein the cover bracket is coupled to the front portion of the body,
wherein the cover bracket comprises a sealing member coupled to a rim thereof to blocks a gap between the cover bracket and the coupling surface.

20. The charging device of claim 19, wherein the cover bracket is shaped to define an exhaust hole that permits heat generated by the display panel to dissipate therethrough.
